(19) United States
(12) Patent Application Publication
(10) Pub. No.: US 2025/0338753 A1
(43) Pub. Date: Oct. 30, 2025

(54) DISPLAY PANEL COVER PLATE AND DISPLAY APPARATUS INCLUDING THE SAME

(71) Applicant: Samsung Display Co., Ltd., Yongin-Si (KR)

(72) Inventor: JUNMO JI, Yongin-si (KR)

(21) Appl. No.: 19/007,235

(22) Filed: Dec. 31, 2024

(30) Foreign Application Priority Data
Apr. 25, 2024 (KR) 10-2024-0055380

(51) Int. Cl. H10K 59/80

(52) U.S. Cl. CPC H10K 59/872; H10K 59/8722

(57) ABSTRACT

A display device includes a display panel including an active area hole located in the active area and defined by a boundary, and a first alignment key located around the boundary of the active area hole, and a cover plate located on the display panel and protecting the display panel, wherein the cover plate includes a first alignment opening that is above the first alignment key and includes an edge.

### CROSS-REFERENCE TO RELATED APPLICATION

This application claims priority to and the benefit of Korean Patent Application No. 10-2024-0055380 filed at the Korean Intellectual Property Office on Apr. 25, 2024, the entire contents of which are incorporated herein by reference.

### BACKGROUND

### (a) Field

The present disclosure relates to a display panel cover plate that is attached to one side of a display panel to protect the display panel, and an electronic device including the same.

### (b) Description of the Related Art

Electronic devices such as smartphones and tablets are built with a display device as a user interface, and the display device includes a display panel and a driving circuit that drives the display panel. A light emitting display panel may be applied as the display panel. A cover plate is attached to one side of the display panel to support and protect the display panel, and may serve as a shielding film to block electromagnetic interference from driving circuits or other electrical circuits of electronic devices.

The cover plate can be attached to the display panel, and for this to happen, the cover plate and display panel must first be precisely aligned. To align the cover plate and the display panel, an align key is formed on the display panel, and an opening is formed on the cover plate, and the relative position of the cover plate and the display panel is set based on the align key of the display panel exposed through the opening of the cover plate.

The portion of the display panel exposed through the opening of the cover plate is vulnerable to external shock, which may cause a black spot-shaped defect in a drop test.

### SUMMARY

Embodiments are intended to facilitate precise alignment of a cover plate and the display panel and to reduce openings vulnerable to external shock.

A display device according to an embodiment includes a display panel having sides and including an active area hole located in the active area and defined by a boundary, and a first alignment key located around the boundary of the active area hole, and a cover plate located on the display panel and protecting the display panel, wherein the cover plate includes a first alignment opening that exposes the first alignment key and includes an edge.

The cover plate may include a hole opening exposing the active area hole, and the first alignment opening may be connected to the hole opening.

The first alignment opening may include a plurality of openings symmetrically arranged with respect to the hole opening.

The first alignment opening may include four openings symmetrically arranged with respect to the hole opening.

The first alignment opening may be a circular opening formed with the edge being spaced apart from the boundary of the active area hole by a constant width. The first alignment opening may be larger than the active area hole.

The first alignment opening may be positioned above each of the first alignment keys around the boundary of the active area hole.

The display panel may further include a second alignment key adjacent to at least one of the sides, and the cover plate may further include a second alignment opening above the second alignment key.

The second alignment key may comprise a plurality of second alignment keys, and the second alignment opening may comprise a plurality of second alignment openings.

The plurality of second alignment openings may be located adjacent to a side of the cover plate that is aligned with the side of the display panel having the second alignment key.

The first alignment key and the second alignment key may be located on an opaque material layer included in at least one of a display part, a touch part, and an anti-reflection part of the display panel.

The cover plate may include a hole opening exposing the active area hole, and the first alignment opening may be connected to the hole opening.

The first alignment opening may include a plurality of openings arranged symmetrically with respect to the hole opening.

The first alignment opening may include four openings symmetrically arranged with respect to the hole opening.

The first alignment opening may be a circular opening with an edge being spaced apart from the boundary of the active area hole by a constant width. The first alignment opening may be larger than the active area hole.

The first alignment opening may expose the first alignment key that is around the active area hole in its entirety.

The display panel may be a foldable panel that is able to be folded or bent at a predetermined area, and the cover plate may be for a foldable panel that is able to be folded or bent in an area that is aligned with the predetermined area of the display panel.

The cover plate according to one embodiment is attached to a surface of a display panel to protect the display panel that includes an active area hole located in an active area and having a boundary. A first alignment key may be located outside the boundary of the active area hole. A hole opening in the cover plate may be aligned with the active area hole in the display panel, and a first alignment opening may be located adjacent to the hole opening and expose the first alignment key in the display panel.

The embodiment may further include a second alignment opening above a second alignment key located at an edge of the display panel.

The first alignment opening may include a plurality of openings symmetrically arranged adjacent to the hole opening.

The first alignment opening may be aa circular opening formed with a constant width outside the boundary of the active area hole in plan view, and may expose all of the first alignment keys around the active area hole.

According to embodiments, the opening formed in the cover plate to align with the display panel can be reduced, thereby improving the durability of the display device.

### BRIEF DESCRIPTION OF THE DRAWINGS

FIG. 1 is a layout diagram of a cover plate and a display panel aligned in a display device according to an embodiment.

FIG. 2 is an enlarged view of the alignment key and the opening of a cover plate around the HIAA (hole in active area) hole in FIG. 1, and indicates alignment reference coordinates.

FIG. 3 is an enlarged view of the opening located on the outer side of a cover plate in FIG. 1 and indicates alignment reference coordinates.

FIG. 4 is a cross-sectional view of a display panel applied to a display device according to an embodiment.

FIG. 5 is a layout view of a cover plate and a display panel aligned in a display device according to another embodiment.

FIG. 6 to FIG. 8 are enlarged views of an alignment key around a hole in the active area HIAA hole and an opening of a cover plate in a display device according to another embodiment.

### DETAILED DESCRIPTION OF THE EMBODIMENTS

With reference to the attached drawings, the embodiments will be described in detail so that those skilled in the art can make and use the present disclosure.

In the drawings, the size and thickness of each component are arbitrarily indicated for convenience of explanation.

When a part of a layer, membrane, region, or plate is said to be “above” or “on” another part, this includes not only being “directly on” another part, but also having another part in between. Conversely, when a composition is said to be “directly above” another composition, it means that there is no other composition in between.

Throughout the specification, it means that a certain part may further include other components, unless there is a statement to the contrary that it “includes” a certain component.

Throughout the specification, “connected” does not mean only the case where two or more components are directly connected, but also when two or more components are indirectly connected through other components, physically connected, or electrically connected. In addition to cases, it may include cases where each part, which is referred to by a different name depending on location or function, but is substantially integrated, is connected to each other.

In the drawing, the symbols “x”, “y”, and “z” are used to indicate directions, where “x” is the first direction, “y” is the second direction perpendicular to the first direction, and “z” is the third direction perpendicular to both the first and second directions. The first direction x, the second direction y, and the third direction z may correspond to the horizontal direction, vertical direction, and thickness direction of the display device, respectively.

Unless otherwise specified in the specification, “overlap” means overlap in the third direction z.

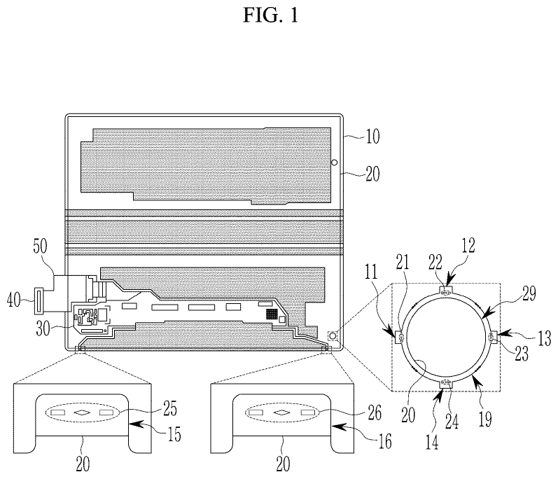

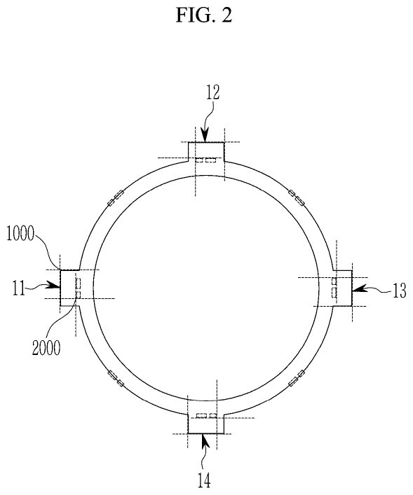

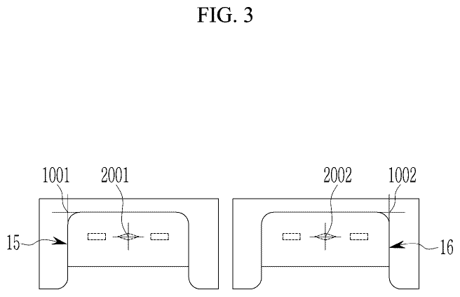

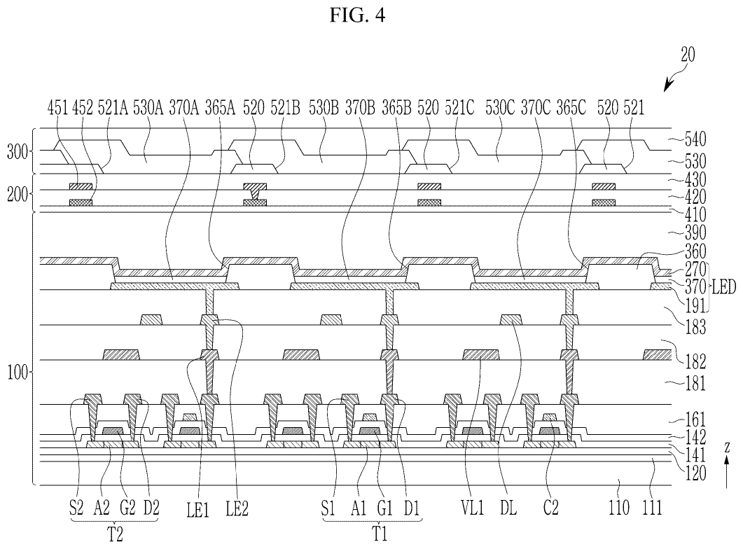

FIG. 1 is a layout diagram of a cover plate and a display panel aligned in a display device according to an embodiment. FIG. 2 is an enlarged view of the alignment key and the opening of the cover plate around the HIAA (hole in active area) hole in FIG. 1, and indicates alignment reference coordinates. FIG. 3 is an enlarged view of the opening located on the outer side of the cover plate in FIG. 1 and indicates alignment reference coordinates. FIG. 4 is a cross-sectional view of a display panel applied to a display device according to an embodiment. “HIAA hole” is herein also referred to as “active area hole.”

Referring to FIG. 1, a display device according to an embodiment includes the cover plate 10, a display panel 20, a printed circuit board 30 on which a driving circuit including an integrated circuit chip, etc. is located, and a connection terminal 40, and may include a flexible circuit film 50 connecting the connection terminal 40 and the printed circuit board 30.

The cover plate 10 can protect the display panel 20 from the environment behind the display panel 20 (e.g., shock, electromagnetic waves, heat, noise, etc.). The cover plate 10 may be called a protective sheet, a lower sheet, etc. The cover plate 10 may include front and side portions respectively corresponding to the front and side portions of the display panel 20, but may include side openings 15 and 16 corresponding to side portions of the display panel 20. In other words, the cover plate 10 may include openings that overlap or cover the front and side parts of the display panel 20, but it may include side openings 15 and 16 exposing the side portions of the display panel 20. The cover plate 10 may be for a foldable panel that can be folded or bent in a predetermined area that is aligned with the bendable or foldable portion of the display panel 20.

The display panel 20 may be a light emitting display panel or a foldable panel that can fold or bend the screen. The display panel 20 may have a HIAA (hole in active area) hole 29 formed in an active area and a hole for disposing a camera lens, etc. An “active area,” as used herein, is a portion of the display panel 20 that displays an image. The shape of the HIAA hole 29 is defined by a boundary. Although the boundary is depicted as being circular in the embodiments depicted in this disclosure, this is not a limitation of the disclosure. The display panel 20 may include alignment keys 21, 22, 23, 24, 25, and 26 located around the boundary of the HIAA hole 29 and also on an edge of a side (e.g., FIG. 1 shows alignment keys 25 and 26 positioned on an edge of a side of the display panel 20). The display panel 20 will be described in more detail later.

The cover plate 10 may include a hole opening 19 that is aligned with the HIAA hole 29 of the display panel 20. Two elements being “aligned,” as used herein, means one is on top of the other in the depth direction, which is the direction orthogonal to the surface depicted in FIG. 1. Side openings 15 and 16 formed on the edge of the cover plate 10 expose the alignment keys 25 and 26 located on the edge of the display panel 20 and some area adjacent to the alignment keys 25, 26. The hole opening 19 may include branch openings 11, 12, 13, and 14 that expose the alignment keys 21, 22, 23, and 24 outside the HIAA hole 29 of the display panel 20. The branch openings 11, 12, 13, and 14 may be arranged symmetrically with respect to the hole opening 19 and may be connected to the hole opening 19. The edge of the side openings 15 and 16 and the branch openings 11, 12, 13, and 14 can be used to achieve an alignment of the display panel 20 and the cover plate 10. The side openings 15, 16 and the branch openings 11, 12, 13, 14 may be collectively referred to as alignment openings.

A plurality of alignment keys used when forming the HIAA hole 29 are located around the HIAA hole 29 of the display panel 20, and the branch openings 11, 12, 13, and 14 exposing some of the alignment keys are connected to the cover plate. By being formed in the cover plate 10, the alignment key used to position the HIAA hole 29 can also be used to align the cover plate 10 and the display panel 20.

Referring to FIGS. 2 and 3, alignment keys 21, 22, 23, 24, 25, and 26 are formed on the display panel 20 and side openings 15 and 16 are formed on the cover plate 10. The branch openings 11, 12, 13, and 14 may be used to align the display panel 20 and the cover plate 10. First, as shown in FIG. 2, the cover plate 10 is positioned so that the horizontal and vertical sides of the branch openings 11, 12, 13, and 14 align with the first alignment coordinates 1000, and the position of the display panel 20 is adjusted so that the horizontal and vertical sides of the alignment keys 21, 22, 23, and 24 around the HIAA hole 29 align with the second alignment coordinates 2000, allowing the cover plate 10 and display panel 20 to be aligned. Additionally, as shown in FIG. 3, the cover plate 10 is positioned so that the horizontal and vertical sides of the side openings 15 and 16 align with the third alignment coordinates 1001 and 1002, and the position of the display panel 20 is adjusted so that the fourth alignment coordinates 2001 and 2002 are located in the center of the alignment keys 25 and 26 that are positioned on or adjacent to the edge of the display panel 20, allowing the cover plate 10 and the display panel 20 to be aligned. Position adjustment for alignment can be performed by moving the display panel 20 or by moving the cover plate 10. The alignment of FIG. 2 and the alignment of FIG. 3 may be performed simultaneously.

The display panel 20 and the alignment keys 21, 22, 23, 24, 25, and 26 will be described with reference to FIG. 4.

The portion shown in FIG. 4 may correspond to approximately three pixel areas in the display area.

Referring to FIG. 4, the display panel 20 according to an embodiment may include a display part 100, a touch part 200, and an anti-reflection part 300.

The display part 100 basically includes a substrate 110, a first transistor T1 and a second transistor T2 formed on the substrate 110, and a light emitting diode LED connected to the first transistor T1. A light emitting diode LED may correspond to a pixel PX.

The substrate 110 may be a flexible substrate containing a polymer such as polyimide, polyamide, or polyethylene terephthalate. The substrate 110 may be a glass substrate.

A barrier layer 111 that prevents the penetration of moisture, oxygen, etc., may be positioned on the substrate 110. The barrier layer 111 may include an inorganic insulating material such as a silicon nitride SiNₓ, a silicon oxide SiOₓ, or a silicon oxynitride SiOₓN_{y}, and may be a single layer or multiple layers.

A buffer layer 120 may be located on the barrier layer 111. The buffer layer 120 improves the characteristics of the semiconductor layer by blocking impurities from the substrate 110 when forming the semiconductor layer, and can relieve the stress of the semiconductor layer by flattening the surface of the substrate 110. The buffer layer 120 may include an inorganic insulating material such as a silicon oxide, a silicon nitride, or a silicon oxynitride. The buffer layer 120 may include amorphous silicon.

Semiconductor layers A1 and A2 may be located on the buffer layer 120. The semiconductor layers A1 and A2 may include a first region, a second region, and a channel region between these regions. The semiconductor layers A1 and A2 may include polycrystalline silicon.

A first gate insulating layer 141 may be located on the semiconductor layers A1 and A2. The first gate insulating layer 141 may include an inorganic insulating material such as a silicon nitride SiNₓ, a silicon oxide SiOₓ, or a silicon oxynitride SiOₓN_{y}, and may be a single layer or a multilayer.

A first gate conductive layer that may include gate electrodes G1, G2, etc. may be located on the first gate insulating layer 141. The first gate conductive layer may be formed from the same material in the same process. The first gate conductive layer may include molybdenum (Mo), aluminum (Al), copper (Cu), titanium (Ti), etc., and may be a single layer or multiple layers.

A second gate insulating layer 142 may be located on the first gate conductive layer. The second gate insulating layer 142 may include an inorganic insulating material such as a silicon nitride, a silicon oxide, or a silicon oxynitride, and may be a single layer or a multilayer.

A second gate conductive layer that may include the upper electrode C2 of the storage capacitor may be located on the second gate insulating layer 142. The upper electrode C2 may overlap the gate electrode G1, and the upper electrode C2, the gate electrode G1, and the second gate insulating layer 142 between them may form a storage capacitor. The second gate conductive layer may be formed from the same material in the same process. The second gate conductive layer may include molybdenum (Mo), aluminum (Al), copper (Cu), titanium (Ti), etc., and may be a single layer or a multilayer.

A first interlayer insulating layer 161 may be located on the second gate conductive layer. The first interlayer insulating layer 161 may include an inorganic insulating material such as a silicon nitride, a silicon oxide, or a silicon oxynitride, and may be a single layer or a multilayer. When the first interlayer insulating layer 161 has multiple layers, the lower layer may include a silicon nitride, and the upper layer may include a silicon oxide.

A first data conductive layer that may include first electrodes S1 and S2, second electrodes D1, D2, etc. may be positioned on the first interlayer insulating layer 161. The first electrode S1 and the second electrode D1 may be connected to the first and second regions of the semiconductor layer A1 through contact holes formed in the insulating layers 141, 142, and 161, respectively. One of the first electrode S1 and the second electrode D1 may be a source electrode and the other may be a drain electrode. The first electrode S2 and the second electrode D2 may be respectively connected to the first and second regions of the semiconductor layer A2 through contact holes formed in the insulating layers 141, 142, and 161. One of the first electrode S2 and the second electrode D2 may be a source electrode and the other may be a drain electrode. The first data conductive layer may be formed from the same material in the same process. The first data conductive layer is aluminum (Al), platinum (Pt), palladium (Pd), silver (Ag), magnesium (Mg), gold (Au), nickel (Ni), neodymium (Nd), iridium (Ir), chromium (Cr), calcium (Ca), molybdenum (Mo), titanium (Ti), tungsten (W), copper (Cu), etc., and may be a single layer or multiple layers. For example, the first data challenge layer may include a lower layer containing refractory metals such as molybdenum, chromium, tantalum, and titanium, a middle layer containing metals with low resistivity such as aluminum, copper, and silver, and an upper layer containing refractory metals. For example, the first data conductive layer may have a triple-layer structure such as titanium/aluminum/titanium Ti/Al/Ti.

The semiconductor layer A1, the gate electrode G1, the first electrode S1, and the second electrode D1 may form the first transistor T1. The first transistor T1 may be a driving transistor or a transistor connected to one electrode of the driving transistor. The semiconductor layer A2, the gate electrode G2, the first electrode S2, and the second electrode D2 may form the second transistor T2. The second transistor T2 may be a transistor connected to the gate electrode G1.

A first planarization layer 181 may be located on the first data conductive layer. The first planarization layer 181 may be an organic insulating layer. For example, the first planarization layer 181 may include organic insulating materials such as general-purpose polymers like poly(methyl methacrylate) and polystyrene, polymer derivatives with phenolic groups, acrylic polymers, imide polymers, polyimides, and siloxane polymers.

A second data conductive layer that may include a driving voltage line VL1, a first connection electrode LE1, etc. may be positioned on the first planarization layer 181. The first connection electrode LE1 may be connected to the second electrode D1 of the first transistor T1 through a contact hole formed in the first planarization layer 181. The second data conductive layer may be formed from the same material in the same process.

The second data conductive layer is aluminum (Al), platinum (Pt), palladium (Pd), silver (Ag), magnesium (Mg), gold (Au), nickel (Ni), neodymium (Nd), iridium (Ir), chromium (Cr), calcium (Ca), molybdenum (Mo), titanium (Ti), tungsten (W), copper (Cu), etc., and may be a single layer or multiple layers. For example, the second data conductive layer may have a triple-layer structure such as titanium/aluminum/titanium Ti/Al/Ti.

A second planarization layer 182 may be located on the second data conductive layer. The second planarization layer 182 may be an organic insulating layer. For example, the second planarization layer 182 includes organic insulating materials such as general-purpose polymers such as poly(methyl methacrylate) and polystyrene, polymer derivatives with phenolic groups, acrylic polymers, imide polymers, polyimide, and siloxane polymers.

A third data conductive layer that may include a data line DL, a second connection electrode LE2, etc. may be located on the second planarization layer 182. The second connection electrode LE2 may be connected to the first connection electrode LE1 through a contact hole formed in the second planarization layer 182. The second data conductive layer may be formed from the same material in the same process. The third data conductive layer is aluminum (Al), platinum (Pt), palladium (Pd), silver (Ag), magnesium (Mg), gold (Au), nickel (Ni), neodymium (Nd), iridium (Ir), chromium (Cr), nickel (Ni), calcium (Ca), molybdenum (Mo), titanium (Ti), tungsten (W), copper (Cu), etc., and may be a single layer or multiple layers. For example, the third data conductive layer may have a triple-layer structure such as titanium/aluminum/titanium (Ti/Al/Ti).

Although it has been explained that the second data conductive layer may include a driving voltage line VL1 and the third data conductive layer may include a data line DL, the signal lines that each data conductive layer may include may vary. For example, the second data conductive layer may include a driving voltage line VL1 and a data line DL.

A third planarization layer 183 may be located on the third data conductive layer. The third planarization layer 183 may be an organic insulating layer. For example, the third planarization layer 183 includes organic insulating materials such as general-purpose polymers such as poly(methyl methacrylate) and polystyrene, polymer derivatives with phenolic groups, acrylic polymers, imide polymers, polyimide, and siloxane polymers.

A pixel conductive layer including a pixel electrode 191 may be positioned on the third planarization layer 183. The pixel electrode 191 may be connected to the second connection electrode LE2 through a contact hole formed in the second planarization layer 182. The pixel electrode 191 is electrically connected to the second electrode D1 and can receive a driving current that controls the brightness of the light emitting diode LED. The pixel conductive layer may be formed from the same material in the same process. The pixel conductive layer may include metals such as silver (Ag), lithium (Li), calcium (Ca), aluminum (Al), magnesium (Mg), and gold (Au). The pixel conductive layer may include a transparent conductive oxide TCO such as indium tin oxide ITO or indium zinc oxide IZO.

A pixel defining layer 360 may be located on the pixel conductive layer. The pixel defining layer 360 may have pixel openings 365A, 365B, and 365C above the pixel electrode 191. The pixel defining layer 360 may include organic insulating materials such as general-purpose polymers such as poly(methyl methacrylate) and polystyrene, polymer derivatives with phenolic groups, acrylic polymers, imide polymers, polyimide, and siloxane polymers. The pixel defining layer 360 may be a black pixel defining layer 360 containing black dye or pigment. The black pixel definition layer 360 can improve the contrast ratio and prevent reflection by the metal layer located below.

The light emitting layers 370A, 370B, and 370C may be located on the pixel electrode 191. At least a portion of the light emitting layers 370A, 370B, and 370C may be located in the pixel openings 365A, 365B, and 365C. The light-emitting layers 370A, 370B, and 370C may include a material layer that uniquely emits light of basic colors such as red, green, and blue. The light emitting layers 370A, 370B, and 370C may have a structure in which material layers emitting light of different colors are stacked. In addition to the light emitting layers 370A, 370B, and 370C, at least one of a hole injection layer, a hole transport layer, an electron transport layer, and an electron injection layer may be positioned on the pixel electrode 191.

A common electrode 270 may be positioned on the light emitting layers 370A, 370B, and 370C and the pixel defining layer 360. The common electrode 270 may be commonly provided to all pixels PX. The common electrode 270 is made of calcium (Ca), barium (Ba), magnesium (Mg), aluminum (Al), silver (Ag), platinum (Pt), palladium (Pd), gold (Au), nickel (Ni), neodymium (Nd), iridium (Ir), chromium (Cr), and lithium (Li). The common electrode 270 may include a transparent conductive oxide TCO such as indium tin oxide ITO or indium zinc oxide IZO.

The pixel electrode 191, the light emitting layers 370A, 370B, and 370C, and the common electrode 270 form a light emitting diode LED. The pixel electrode 191 may be an anode of a light emitting diode LED, and the common electrode 270 may be a cathode of a light emitting diode LED.

An encapsulation layer 390 may be positioned on the common electrode 270. The encapsulation layer 390 can seal the light emitting diode LED and prevent moisture and oxygen from penetrating from the outside. The encapsulation layer 390 may be a thin film encapsulation layer including one or more inorganic layers and one or more organic layers. For example, the encapsulation layer 390 may have a triple-layer structure of inorganic layer/organic layer/inorganic layer.

The touch part 200 may be positioned on the encapsulation layer 390.

The touch part 200 may include a first insulating layer 410 located on the encapsulation layer 390. The first insulating layer 410 may cover the encapsulation layer 390, protect the encapsulation layer 390, and prevent moisture permeation. The first insulating layer 410 can reduce parasitic capacitance between the common electrode 270 and the touch electrode 451.

A first touch conductive layer that may include a bridge 452, etc. may be located on the first insulating layer 410, and a second insulating layer 420 may be located on the first touch conductive layer. A second touch conductive layer that may include a touch electrode 451 may be located on the second insulating layer 420, and a passivation layer 430 may be located on the second touch conductive layer.

The touch electrode 451 may include first touch electrodes and second touch electrodes forming a mutual sensing capacitor. The bridge 452 may electrically connect the first touch electrodes or the second touch electrodes. For example, the first touch electrodes that are adjacent but separated from each other may be connected to the bridge 452 through contact holes formed in the second insulating layer 420 and electrically connected through the bridge 452.

The first insulating layer 410 and the second insulating layer 420 may include an inorganic insulating material such as a silicon nitride, a silicon oxide, or a silicon oxynitride, and may be a single layer or a multilayer. The passivation layer 430 may include an inorganic insulating material such as a silicon nitride, a silicon oxide, or a silicon oxynitride, or an organic material such as an acrylic polymer or polyimide resin.

The first touch electrode layer and the second touch electrode layer may have a mesh shape with openings that overlap the pixels PX. The first touch electrode layer may be formed of the same material in the same process. The second touch electrode layer may be formed of the same material in the same process. The first touch electrode layer and the second touch electrode layer may include metal such as aluminum (Al), copper (Cu), titanium (Ti), molybdenum (Mo), silver (Ag), chromium (Cr), and nickel (Ni).

The anti-reflection part 300 may be located on the touch part 200.

The anti-reflection part 300 may include a light blocking layer 520 and color filters 530A, 530B, and 530C.

The light blocking layer 520 may overlap the pixel defining layer 360 of the display part 100 and may be narrower than the pixel defining layer 360. The light blocking layer 520 may have openings 521A, 521B, and 521C above the pixel openings 365A, 365B, and 365C of the pixel defining layer 360.

Color filters 530A, 530B, and 530C may be positioned on the light blocking layer 520. Most of the color filters 530A, 530B, and 530C may be in and around the openings 521A, 521B, and 521C of the light blocking layer 520. An overcoat layer 540 may be located on the color filters 530A, 530B, and 530C.

The anti-reflection part 300 can prevent external light that is incident on the display panel 20 from being reflected by wiring or the like and being seen by a user. The light blocking layer 520 and the color filters 530A, 530B, and 530C may be combined to function as an anti-reflection layer. In this structure, a polarizing layer as an anti-reflection layer may not be required, and thus light output efficiency can be increased and the thickness of the display panel 20 can be reduced.

As described above, the display part 100 of the display panel 20 includes layers made of opaque materials that can be recognized, such as the first gate conductive layer, the second gate conductive layer, the first data conductive layer, the second data conductive layer, the third data conductive layer, the pixel conductive layer, and the pixel defining layer 360. In addition, the touch part 200 and the anti-reflection part 300 also include layers made of an opaque material that can be seen, such as a first touch conductive layer, a second touch conductive layer, and a light blocking layer 520, respectively. The alignment keys 21, 22, 23, 24, 25, and 26 may be formed on any one of these layers or distributed across a combination thereof.

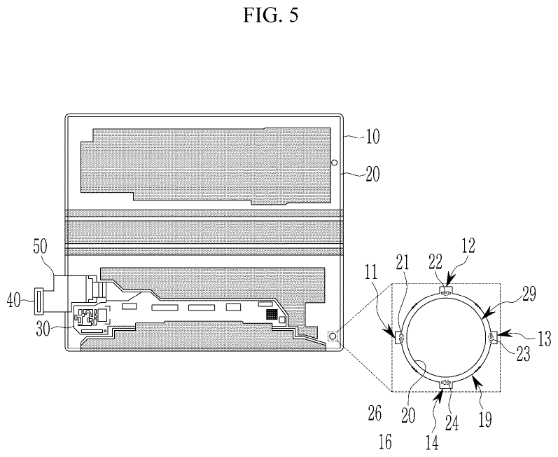

FIG. 5 is a layout view of the cover plate and a display panel aligned in a display device according to another embodiment.

In the embodiment of FIG. 5, the side openings 15 and 16 are absent, unlike in the embodiment of FIG. 1. The cover plate 10 may only include a hole opening 19 that exposes the HIAA hole 29 of the display panel 20 and branch openings 11, 12, 13, and 14 formed around the hole opening 19, which expose the alignment keys 21, 22, 23, and 24 surrounding the HIAA hole 29. The cover plate 10 and the display panel 20 can be aligned using four distributed branch openings 11, 12, 13, and 14 and four alignment keys 21, 22, 23, and 24.

Depending on the embodiment, the number of branch openings may be 2, 3, or 5 or more. Depending on the embodiment, one of the side openings 15 and 16 of FIG. 1 may be maintained and the other may be omitted.

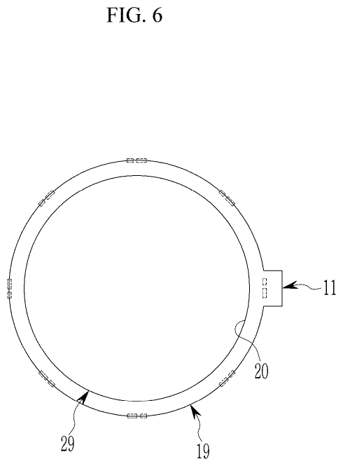

FIG. 6 to FIG. 8 are enlarged illustrations of an alignment key around a HIAA (hole in active area) hole 29 and an opening of the cover plate 10 in a display device according to another embodiment.

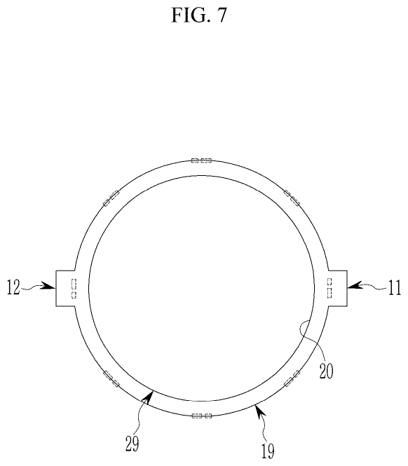

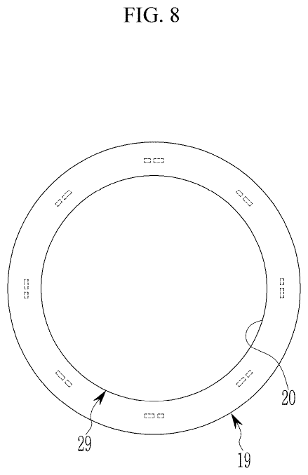

The embodiment of FIG. 6 is an embodiment in which only one branch opening 11 is disposed. As in the embodiment of FIG. 1, the cover plate 10 and the display panel 20 can be aligned using the side openings 15 and 16 and the branch openings 11. Depending on the embodiment, one side opening or three or more side openings may be formed, and the side openings may be located on the top or side of the cover plate 10 instead of the bottom. In the embodiments of FIG. 6, FIG. 7, and FIG. 8, the hole opening 19 is larger than the HIAA hole 29, and their centers are aligned such that in plan view, the edge of the hole opening 19 circumscribes the boundary of the HIAA hole 29 and one or more alignment keys.

The embodiment of FIG. 7 has two branch openings 11 and 12 arranged as far apart as possible while being adjacent to the hole opening 19. The branch openings 11 and 12 are arranged in symmetrical positions with respect to the hole opening 19. Using these two branch openings 11 and 12, the cover plate 10 and the display panel 20 can be aligned, and as in the embodiment of FIG. 1, one or more edge openings 15 and 16 can be formed, and together with these, the cover plate 10 and the display panel 20 can also be aligned.

FIG. 8 is an embodiment where the radius of the hole opening 19 is made large enough to expose the alignment key around the HIAA hole 29. In other words, the alignment opening is formed in a circular shape such that in plan view, its edge is distanced from the boundary of the active area hole 29 by a constant width along the circumference of the HIAA hole 29. The alignment opening may be larger than the HIAA hole 29. The cover plate 10 and the display panel 20 can be aligned by ensuring that the distance between the alignment keys and the edge of the hole opening 19 is constant.

Although the embodiments of the present disclosure have been described in detail above, the scope of the present disclosure is not limited thereto, and various modifications and improvements made by those skilled in the art using the basic concepts of the present disclosure defined in the following claims are also possible.

What is claimed is:

1. A display device, comprising:
a display panel having sides and including an active area hole located in the active area and defined by a boundary, and a first alignment key located around the boundary of the active area hole; and
a cover plate located on the display panel and protecting the display panel,
wherein the cover plate includes a first alignment opening that exposes the first alignment key and includes an edge.

2. The display device of claim 1, wherein
the cover plate includes a hole opening exposing the active area hole, and the first alignment opening is connected to the hole opening.

3. The display device of claim 2, wherein
the first alignment opening includes a plurality of openings symmetrically arranged with respect to the hole opening.

4. The display device of claim 3, wherein
the first alignment opening includes four openings symmetrically arranged with respect to the hole opening.

5. The display device of claim 2, wherein
the first alignment opening is a circular opening with the edge being spaced apart from the boundary of the active area hole by a constant width, wherein the first alignment opening is larger than the active area hole.

6. The display device of claim 5, wherein
the first alignment opening is positioned above each of the first alignment keys around the boundary of the active area hole.

7. The display device of claim 1, wherein
the display panel further includes a second alignment key adjacent to at least one of the sides, and
the cover plate further includes a second alignment opening above the second alignment key.

8. The display device of claim 7, wherein
the second alignment key and the second alignment opening comprise a plurality of second alignment keys and a plurality of second alignment openings, respectively.

9. The display device of claim 8, wherein
the plurality of second alignment openings are located adjacent to a side of the cover plate that is aligned with the side of the display panel having the second alignment key.

10. The display device of claim 7, wherein
the first alignment key and the second alignment key are located on an opaque material layer included in at least one of a display part, a touch part, and an anti-reflection part of the display panel.

11. The display device of claim 7, wherein
the cover plate includes a hole opening exposing the active area hole, and the first alignment opening is connected to the hole opening.

12. The display device of claim 11, wherein
the first alignment opening includes a plurality of openings symmetrically arranged with respect to the hole opening.

13. The display device of claim 12, wherein
the first alignment opening includes four openings symmetrically arranged with respect to the hole opening.

14. The display device of claim 11, wherein
the first alignment opening is a circular opening with an edge being spaced apart from the boundary of the active area hole by a constant width, wherein the first alignment opening is larger than the active area hole.

15. The display device of claim 14, wherein
the first alignment opening exposes the first alignment key that is around the active area hole in its entirety.

16. The display device of claim 1, wherein
the display panel is a foldable panel that is able to be folded or bent at a predetermined area, and
the cover plate is a display device for a foldable panel that is able to be folded or bent in an area that is aligned with the predetermined area of the display panel.

17. A cover plate attached to a surface of a display panel, the display panel having an active area hole located in an active area, the active area hole having a boundary, and a first alignment key located outside the boundary of the active area hole, the cover plate comprising:
a hole opening aligned with the active area hole of the display panel; and
a first alignment opening positioned adjacent to the hole opening and expose the first alignment key of the display panel.

18. The cover plate of claim 17, further comprising
a second alignment opening above a second alignment key located at an edge of the display panel.

19. The cover plate of claim 17, wherein
the first alignment opening includes a plurality of openings symmetrically disposed adjacent to the hole opening.

20. The cover plate of claim 17, wherein
the first alignment opening is a circular opening formed with a constant width outside the boundary of the active area hole in plan view, and the first alignment opening exposing all of the first alignment keys around the active area hole.
